(19) United States
(12) Patent Application Publication
(10) Pub. No.: US 2026/0068464 A1
(43) Pub. Date: Mar. 5, 2026

(54) DISPLAY PANEL AND DISPLAY DEVICE

(71) Applicant: HKC CORPORATION LIMITED, Shenzhen (CN)

(72) Inventors: YAO LI, Shenzhen (CN); Lidan YE, Shenzhen (CN)

(21) Appl. No.: 19/310,955

(22) Filed: Aug. 27, 2025

(30) Foreign Application Priority Data
Aug. 30, 2024 (CN) 202411218962.4

(51) Int. Cl. H10K 59/131; H10K 102/00

(52) U.S. Cl. CPC H10K 59/131; H10K 2102/311

(57) ABSTRACT

A display panel and a display device are provided. The display panel includes a substrate defining pixel island regions disposed in an array and flexible regions, pixel layers, and stretchable traces. Each of the flexible regions is defined between corresponding two adjacent pixel island regions. Each of the pixel layers is disposed in a corresponding one of the pixel island regions. The stretchable traces are disposed on the flexible regions and are made from a conductive hydrogel material. The conductive hydrogel material includes a hydrogel material and a conductive additive doped in the hydrogel material. The hydrogel material is a main material of the conductive hydrogel material. When the display panel is bent, stretched, or folded, since the stretchable traces are stretchable, disconnection of data lines, scanning lines, and other signal transmission lines is avoided, thereby improving display stability and the quality of the display panel.

### CROSS-REFERENCE TO RELATED APPLICATION

The present disclosure claims foreign priority to Chinese Patent Application No. CN202411218962.4, titled “DISPLAY PANEL AND DISPLAY DEVICE”, filed on Aug. 30, 2024 in the China National Intellectual Property Administration, and the entire contents of which are hereby incorporated by reference.

### TECHNICAL FIELD

The present disclosure relates to a field of display technology, and in particular to a display panel and a display device.

### BACKGROUND

Currently, flexible Organic Light-Emitting Diode (OLED) display panels are gaining more and more attention. The flexible OLED display panels are display screens that are deformable in various ways, such as being rolled up, being stretched, or being folded. For the flexible OLED display panels, the main components thereof generally include scanning lines and data lines. The scanning lines and the data lines are crossed over on a flexible substrate, and the scanning lines and data lines jointly define pixel units disposed in a matrix. Since each of the pixel units includes a Thin Film Transistor (TFT) structure, a light-emitting unit structure, and a corresponding driving circuit, the flexible OLED display panels have characteristics of high pixel density and dense wiring. Therefore, when rolling up, stretching, or folding the flexible OLED display panels, the most common concern is stability of a pixel display before and after deformation and stretchable properties of stretchable metal traces.

Therefore, how to ensure stable signal transmission of the data lines, the scanning lines, and other signal transmission lines of the flexible OLED display panels before and after being rolled up, stretched, or folded is a technical problem that urgently needs to be solved by those skilled in the art.

### SUMMARY

The present disclosure provides a display panel and a display device. By dividing pixel island regions and the flexible regions, and by configuring stretchable traces with a stretching function in the flexible regions, a disconnection phenomenon of data lines, scanning lines, and other signal transmission lines of the display panel before and after being rolled up, being stretched, or being folded is alleviated, the display stability of pixels before and after the display panel is rolled up, is stretched, or is folded is improved, and the quality of the display panel is also enhanced.

The present disclosure provides a display panel. The display panel includes a substrate defining pixel island regions disposed in an array and flexible regions; pixel layers, and stretchable traces.

Each of the flexible regions is defined between corresponding two adjacent pixel island regions. Each of the pixel layers is disposed on the substrate and is disposed in a corresponding one of the pixel island regions. The stretchable traces are disposed on the substrate and are disposed on the flexible regions.

The stretchable traces are made from a conductive hydrogel material. The conductive hydrogel material includes a hydrogel material and a conductive additive doped in the hydrogel material. The hydrogel material is a main material of the conductive hydrogel material.

Optionally, the hydrogel material includes a sodium alginate-chitosan quaternary ammonium salt hydrogel material. The conductive additive includes at least one of nano-silver particles, copper particles, carbon nanotubes, graphene, and electroactive aniline tetramers.

Optionally, the display panel further includes fixed traces. The fixed traces are disposed on the substrate and are disposed on the pixel island regions. Each of the stretchable traces extends into corresponding two adjacent pixel island regions and is connected to corresponding two of the fixed traces.

Optionally, the display panel further includes conductive connecting portions. Each of the conductive connecting portions wraps a connection joint of a corresponding one of the fixed traces and a corresponding one of the stretchable traces. The conductive connecting portions are made from a conductive gel material.

Optionally, the fixed traces and the stretchable traces are made from the same material.

Optionally, the stretchable traces include first traces and second traces. Each of the second traces is disposed on a corresponding one of the first traces, and the display panel further includes first insulating layers. Each of the first traces is insulated from the corresponding one of the second traces through a corresponding one of the first insulating layers. Each of the first traces partially overlaps with the corresponding one of the second traces in an orthographic projection of the substrate.

Optionally, the first traces extend in a first direction, the second traces extend in a second direction, and the first direction is perpendicular to the second direction. The display panel further includes a second insulating layer. The second insulating layer is disposed between the first traces and the substrate. The first insulating layers are made from an insulating hydrogel material. The second insulating layer is made from at least one of silicon nitride, silicon oxide, and silicon oxynitride.

Optionally, stretchable traces further include third traces, and the third traces are disposed above the second traces. The display panel further includes third insulating layers. Each of the third insulating layers is disposed at an overlapping position of a corresponding one of the second traces and a corresponding one of the third traces. Each of the third insulating layers is disposed between the corresponding one of the second traces and the corresponding one of the third traces. The third insulating layers are formed of an insulating hydrogel material.

Optionally, metal ions are introduced into the pixel island regions from one side or two sides of the substrate for cross-linking to define the pixel island regions, and regions of the substrate configured as the pixel island regions are rigid.

Optionally, the pixel layers include light-emitting units, and each of the light-emitting units is disposed on a corresponding one of the pixel island regions. When the display panel is bent, stretched, rolled up, or folded, each of the light-emitting units disposed on the corresponding one of the pixel island regions is not stretched or bent.

The present disclosure further provides the display device. The display device includes a driving circuit and the display panel mentioned above. The driving circuit is configured to drive the display panel to display.

In the present disclosure, the display panel is divided into the pixel island regions and flexible regions, and the flexible regions refer to regions where the display panel bends, stretches, rolls up, or folds when it is deformed. In the flexible regions, the stretchable traces are formed by the conductive hydrogel material. When the flexible regions are folded and bent, the hydrogel material forming the stretchable traces has good stretching properties, so the stretchable traces do not break due to being stretched, thereby improving wiring stability of the display panel in the flexible regions. In the flexible regions, the stretchable traces with the stretching function are formed to solve the disconnection of the data lines, the scanning lines, and the other signal transmission lines of the display panel before and after being bent, being stretched, or being folded, thereby improving the display stability of the pixels before and after the display panel is rolled up, is stretched, or is folded, and improving the quality of the display panel.

### BRIEF DESCRIPTION OF DRAWINGS

The drawings are included to provide a further understanding of embodiments of the present disclosure, which form portions of the specification and are used to illustrate implementation manners of the present disclosure and are intended to illustrate operating principles of the present disclosure together with the description. Apparently, the drawings in the following description are merely some of the embodiments of the present disclosure, and those skilled in the art are able to obtain other drawings according to the drawings without contributing any inventive labor. In the drawing:

FIG. 1 is a top plan schematic diagram of a display panel according to one embodiment of the present disclosure.

FIG. 2 is a cross-sectional schematic diagram of the display panel taken along the line A-A shown in FIG. 1.

FIG. 3 is a top plan schematic diagram of stretchable traces and fixed traces according to one embodiment of the present disclosure.

FIG. 4 is a top plan schematic diagram of the stretchable traces according to one embodiment of the present disclosure.

FIG. 5 is a cross-sectional schematic diagram of the stretchable traces taken along the line B-B shown in FIG. 4.

FIG. 6 is a schematic diagram showing a manufacturing process of the stretchable traces according to one embodiment of the present disclosure.

FIG. 7 is another schematic diagram showing the manufacturing process of the stretchable traces according to one embodiment of the present disclosure.

FIG. 8 is a schematic diagram of a display device according to one embodiment of the present disclosure.

Reference numerals in the drawings: 100—display panel, 101—pixel island region; 102—flexible region; 110—substrate; 111—pixel layer; 120—stretchable trace; 121—first trace; 122—second trace; 123—third trace; 124—conductive connecting portion; 125—first insulating layer; 126—second insulating layer; 127—third insulating layer; 130—fixed trace; X—first direction; Y—second direction; 200—display device; 210—driving circuit.

### DETAILED DESCRIPTION

It should be understood that terms, specific structures, and function details disclosed herein are only representative and are used for the purpose of describing exemplary embodiments of the present disclosure. However, the present disclosure may be achieved in many alternative forms and shall not be interpreted to be only limited to the embodiments described herein.

In the description of the present disclosure, terms such as “first” and “second” are only used for the purpose of description, rather than being understood to indicate or imply relative importance or hint the number of indicated technical features. Thus, the feature limited by “first” and “second” can explicitly or implicitly include one or more features. In the description of the present disclosure, the meaning of “a plurality of” is two or more unless otherwise specified. In addition, terms such as “upper”, “lower”, “left”, “right”, “vertical”, “horizontal”, etc. indicate direction or position relationships shown based on the drawings, and are only intended to facilitate the description of the present disclosure and the simplification of the description rather than to indicate or imply that the indicated device or element must have a specific direction or be constructed and operated in a specific direction, and therefore, shall not be understood as a limitation to the present disclosure. For those of ordinary skill in the art, the meanings of the above terms in the present disclosure may be understood according to concrete conditions.

The present disclosure is described in detail below with reference to the accompanying drawings and optional embodiments.

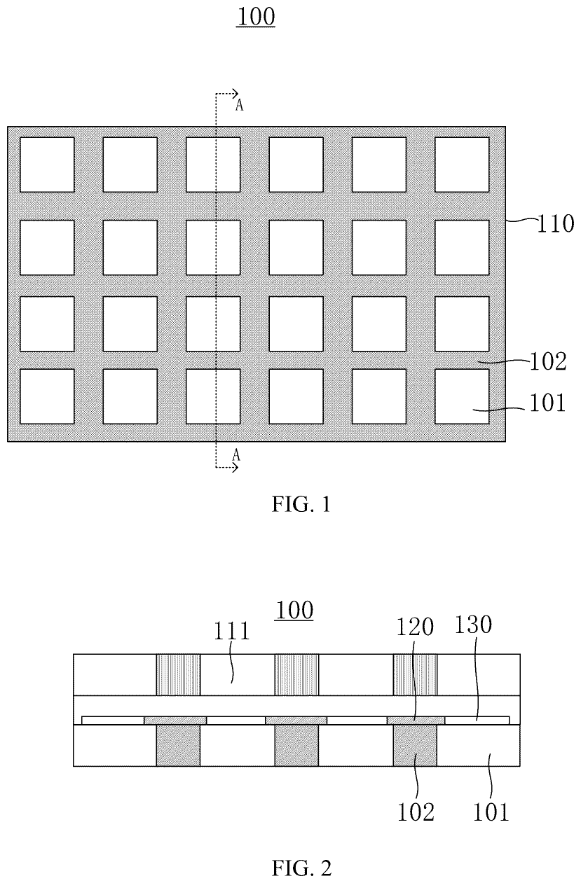

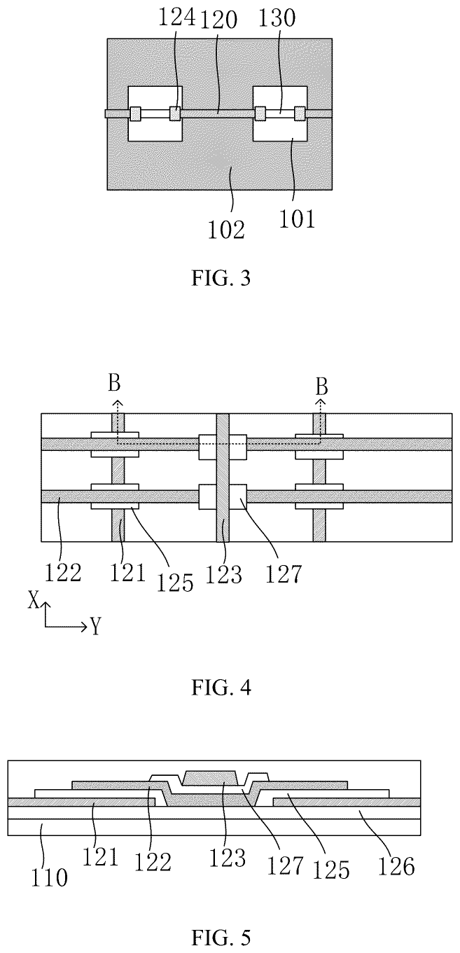

FIG. 1 is a top plan schematic diagram of a display panel according to one embodiment of the present disclosure. FIG. 2 is a cross-sectional schematic diagram of the display panel taken along the line A-A shown in FIG. 1. FIG. 3 is a top plan schematic diagram of stretchable traces and fixed traces according to one embodiment of the present disclosure. As shown in FIGS. 1-3, the present disclosure provides a display panel 100. The display panel 100 includes a substrate 110 defining pixel island regions 101 disposed in an array and flexible regions 102, pixel layers 111, and stretchable traces 120. Each of the flexible regions 102 is defined between corresponding two adjacent pixel island regions 101. Each of the pixel layers 111 is disposed on the substrate 110 and is disposed in a corresponding one of the pixel island regions 101. The stretchable traces 120 are disposed on the substrate 110 and are disposed on the flexible regions 102. The stretchable traces 120 are made from a conductive hydrogel material. The conductive hydrogel material includes a hydrogel material and a conductive additive doped in the hydrogel material. The hydrogel material is a main material of the conductive hydrogel material.

In the present disclosure, the display panel 100 is divided into the pixel island regions 101 and flexible regions 102, and the flexible regions 102 refer to regions where the display panel 100 bends, stretches, rolls up, or folds when it is deformed. In the flexible regions 102, the stretchable traces 120 are formed by the conductive hydrogel material. When the flexible regions 102 are folded and bent, the hydrogel material forming the stretchable traces 120 has good stretching properties, so the stretchable traces 120 do not break due to being stretched, thereby improving wiring stability of the display panel 100 in the flexible regions 102. In the flexible regions 102, the stretchable traces 120 with the stretching function are formed to solve the disconnection of the data lines, the scanning lines, and the other signal transmission lines of the display panel 100 before and after being bent, being stretched, or being folded, thereby improving the display stability of the pixels before and after the display panel 100 is rolled up, is stretched, or is folded, and improving the quality of the display panel 100.

Specifically, each of the pixel island regions 101 of the display panel 100 includes at least one sub-pixel. Each sub-pixel includes a light-emitting unit. Each light-emitting unit may be a white light-emitting unit, a red light-emitting unit, a green light-emitting unit, or a blue light-emitting unit. When each of the pixel island regions 101 includes only a corresponding light-emitting unit, during the process of bending, stretching, rolling, or folding of the display panel 100, the pixel island regions 101 are protected from bending by a rigid material forming the pixel island regions 101, thereby protecting the corresponding sub-pixel disposed in each of the pixel island regions 101 from stretching or bending. Each of the flexible regions 102 is disposed between the corresponding two adjacent pixel island regions 101, and during the process of bending, stretching, rolling, or folding of the display panel 100, the flexible regions 102 are deformed. The flexible regions 102 are generally configured to mount signal connecting lines, etc. The signal connecting lines include but are not limited to data lines, scanning signal lines, and signal transmission lines. The signal connecting lines mounted in the flexible regions 102 generally need to have greater elasticity and toughness. For example, during multiple folding or rolling, the stretchable traces 120 made of a metal material are prone to deformation fatigue or fatigue damage, which may cause the stretchable traces 120 made of the metal material to break. Moreover, since the stretchable traces 120 made of the metal material may cause a large difference in resistance of part of wiring areas when being stretched, an impedance inside the display panel 100 increases, resulting in a large difference in display effect.

In the embodiment, the stretchable traces 120 are made from the conductive hydrogel material. The hydrogel material is synthesized from monomers or polymers (i.e., structural units) by forming a water-permeable cross-linked network. Specifically, monomers are polymerized to form polymers, and then an interpenetrating polymer network (IPN) is formed through a gel process (e.g., a cross-linking method). The hydrogel material is able to retain a large amount of water and maintain a three-dimensional (3D) network structure. The water-permeable cross-linked network includes non-covalent bonds (i.e., physical cross-linking) or covalent bonds (i.e., chemical cross-linking). The hydrogel material is generally a jelly-like solid with elasticity.

In the present disclosure, the conductive hydrogel material is a self-healing hydrogel based on sodium alginate. The self-healing gel refers to a material that is able to automatically repair and restore its original function after being damaged. The sodium alginate [C₆H₇O₆Na] n is a byproduct produced after extracting iodine and mannitol from brown algae such as Sargassum or kelp. The sodium alginate is a linear natural polysaccharide polymer composed of β-1, 4-D-mannuronic acid (β-D-Mannuronic) units (M units) and α-1, 4-L-guluronic acid (α-L-guluronic) units (G units). The difference in a specific molecule gravity and a ratio of two uronic acids (i.e., the M units and the G units) of the sodium alginate results in significant differences in a gelling force, a viscosity, a molecular selectivity, and other characteristics of alginate. Since the sodium alginate contains a large amount of carboxyl groups, the sodium alginate presents a polyanion phenomenon in aqueous solution and produces adhesive substances, making the aqueous solution of the sodium alginate have great viscosity. More importantly, Na+ ions in the G units of the sodium alginate are able to exchange ions with multivalent metal cations (e.g., Zn2+, Fe3+, Ba2+, Cr3+, Ca2+, etc.) in the aqueous solution, so that the G units and the multivalent metal cations are cross-linked to form an egg-box-shaped model, forming a sodium alginate-based hydrogel containing metal ions. The sodium alginate is able to quickly form the hydrogel material under very warm climate conditions. Due to characteristics of good film-forming properties and high strength, sodium alginate is widely used.

The self-healing hydrogel of the embodiment may be a sodium alginate-chitosan quaternary ammonium salt hydrogel. A self-healing mechanism of the sodium alginate-chitosan quaternary ammonium salt hydrogel is mainly based on ion exchange and polymerization. The ion exchange refers to that after the sodium alginate-chitosan quaternary ammonium salt hydrogel breaks, the sodium alginate and chitosan quaternary ammonium salt flow to each other and reunite to form a new ion cross-linked network. The ion exchange promotes ion reassembly at a fracture of the sodium alginate-chitosan quaternary ammonium salt hydrogel and realizes the self-healing of the sodium alginate-chitosan quaternary ammonium salt hydrogel. The polymerization refers to that water molecules in the sodium alginate-chitosan quaternary ammonium salt hydrogel are able to reconnect at the fracture to form a chain structure of water. When the water molecules at the fracture of the sodium alginate-chitosan quaternary ammonium salt hydrogel gradually evaporate or are discharged, the chain structure gradually forms a solid bridge at the fracture, so that the sodium alginate-chitosan quaternary ammonium salt hydrogel is reconnected. The self-healing ability of the polymerization is realized by controlling a concentration of the polymerizer and molecular structures in the sodium alginate-chitosan quaternary ammonium salt hydrogel. In addition, temperature also accelerates a self-healing process, which is not limited by the present disclosure.

Adding a conductive additive to the sodium alginate-chitosan quaternary ammonium salt hydrogel, such as metals (e.g., nano-Ag ions, nano-Cu particles, etc.) or non-metals (e.g., C nanotubes, graphene, electroactive aniline tetramer (AT)), etc.) makes the self-healing gel have high conductivity. In the embodiment, the stretchable traces 120 made from the conductive hydrogel material have high conductivity and stretchability. Especially, a resistance of the stretchable traces 120 reduces after being stretched.

In the embodiment, the hydrogel material includes a sodium alginate-chitosan quaternary ammonium salt hydrogel material. The conductive additive includes at least one of nano-silver particles, copper particles, carbon nanotubes, graphene, and electroactive aniline tetramers.

In one embodiment, the pixel island regions 101 and the flexible regions 102 are formed by changing a material of the substrate 110 of the display panel 100. Specifically, the display panel 100 includes the substrate 110, and the substrate 110 is made from a polymer hydrogel composite material. Metal ions are introduced into the substrate 110 from one side or two sides of the substrate 110 for cross-linking, so as to form the pixel island regions 101. Therefore, the pixel island regions 101 of the substrate have rigidity.

In the embodiment, a polymer hydrogel composite material is configured as a main material of the substrate 110. The polymer hydrogel composite material has certain elasticity and toughness, so that the flexible regions 102 of the substrate 110 have elasticity, which is conducive to rolling up, stretching or bending the display panel 100. By doping a certain concentration of metal ions in the substrate 110 to define the pixel island regions 101, the pixel island regions 101 of the substrate 110 have rigidity. In the process of rolling up, stretching, or bending the display panel 100, since the pixel island regions 101 of the substrate 110 have rigidity, the pixel island regions 101 have a certain degree of tensile resistance, which minimizes deformation and elongation in the pixel island regions 101, thereby protecting components that are unable to be stretched. The flexible regions 102 and the pixel island regions 101 are made to have different characteristics by doping different materials in the substrate 110 made from the same material. In this way, when the display panel 100 is rolled, stretched, or folded, the components disposed in the pixel island regions 101 are not affected, thereby improving the pixel display effect of the flexible display panel 100 and improving the quality of the display panel 100.

The polymer hydrogel composite material includes acrylamide-acrylic acid copolymer P (AAm-co-AA) ion gel. Specifically, basic materials such as polyvinyl alcohol and polyacrylamide are selected, and two monomers with different solubility are randomly copolymerized in an ionic liquid to generate phase-separated elastic domains and rigid domains in situ, thereby obtaining the acrylamide-acrylic acid copolymer P (AAm-co-AA) ion gel that is super-tough and stretchable. Random copolymerization of acrylamide monomers and acrylic acid monomers in 1-ethyl-3-methylimidazolium ethyl sulfate (EMIES) produces a macroscopically homogeneous covalent network and in situ phase separation domains. Polymer-rich rigid phases toughen the acrylamide-acrylic acid copolymer P (AAm-co-AA) ion gel by forming hydrogen bonds between polymer chains, while solvent-rich elastic phases maintain mechanical integrity to achieve large strains. The acrylamide-acrylic acid copolymer P (AAm-co-AA) ion gel has ultra-high fracture strength (e.g., 12.6 MPa), ultra-high fracture energy (e.g., 24 kJ m-2), and ultra-high Young's modulus (e.g., 46.5 MPa). Further, the acrylamide-acrylic acid copolymer P (AAm-co-AA) ion gel also exhibits high stretchability (e.g., 600% strains).

It is understood that based on use of the polymer hydrogel composite material as the main material of the substrate, local modifications of the pixel island regions 101 are realized to change the mechanical properties of different regions of the substrate. For example, ion transfer printing technology and ion ink printing technology are adopted to introduce different amounts of metal ions at different positions on one side or two sides of the substrate made from the polymer hydrogel composite material, and cross-linking densities and mechanical properties of the polymer hydrogel composite material on surfaces of the pixel island regions 101 are changed, so that the substrate is modified. The metal ions doped in the substrate include iron ions, aluminum ions or zinc ions (such as Fe3+, Al3+, Zn2+, etc.). Compared with a solution of splicing flexible materials and rigid materials to form the substrate that is flexible, the present disclosure does not have seams between the flexible materials and the rigid materials, and thus avoids instability in the seams.

Of course, the flexible regions 102 and the pixel island regions 101 of the substrate 110 of the present disclosure are also allowed to be formed by splicing the flexible materials and the rigid materials, and the substrate 110 also adopts the configuration of the stretchable traces 120.

Specifically, the display panel 100 further includes fixed traces 130. The fixed traces 130 are disposed on the substrate 110 and are disposed on the pixel island regions 101. Each of the stretchable traces 120 extends into corresponding two adjacent pixel island regions 101 and is connected to corresponding two of the fixed traces 130.

In the embodiment, by extending each of the stretchable traces 120 into the corresponding two adjacent pixel island regions 101, it avoids a case that a deformation force generated by the stretching and bending of the display panel 100 during the rolling or folding process causes the stretchable traces 120 to deform while the fixed traces 130 are not deformed. Therefore, a connection joint of each of the fixed traces 130 and a corresponding one of the stretchable traces 120 in each of the pixel island regions 101 does not break. As a result, in the embodiment, by extending each of the stretchable traces 120 into the corresponding two adjacent pixel island regions 101, a signal connection failure between the pixel island regions 101 and the flexible regions 102 caused by deformation is avoided.

Furthermore, the display panel 100 further includes conductive connecting portions 124. Each of the conductive connecting portions 124 wraps a connection joint of a corresponding one of the fixed traces 130 and a corresponding one of the stretchable traces 120.

In the embodiment, in order to ensure connection stability at each connection point, an electrical connection between each of the fixed traces 130 and the corresponding one of the stretchable traces 120 is achieved by a corresponding one of the conductive connecting portions 124 made from a conductive material. Specifically, each of the conductive connecting portions 124 partially wraps the corresponding one of the fixed traces 130 and the corresponding one of the stretchable traces 120.

It is understood that each of the fixed traces 130 is connected to the corresponding one of the stretchable traces 120 at the connection joint thereof. In a process of depositing the fixed traces 130 and the stretchable traces 120, the fixed traces 130 and the stretchable traces 120 are respectively one-to-one deposited at connection positions, so that each of the fixed traces 130 is connected to the corresponding one of the stretchable traces 120.

The conductive connecting portions 124 are made from a conductive gel material. The conductive gel material is changed from a gel state to a molten state by light or heating, so that each of the conductive connecting portions 124 wraps the connection joint of the corresponding one of the fixed traces 130 and the corresponding one of the stretchable traces 120. As a result, each of the fixed traces 130 and the corresponding one of the stretchable traces 120 are connected together. In one specific embodiment, a groove is defined at each of the connection positions, and the conductive gel material is first filled to a bottom of each groove. After each of the fixed traces 130 and the corresponding one of the stretchable traces 120 are connected, the conductive gel material is placed again above each of the fixed traces 130 and the corresponding one of the stretchable traces 120, and each of the conductive connecting portions is formed by heating and melting, so as to wrap the connection joint of each of the fixed traces 130 and the corresponding one of the stretchable traces 120.

Of course, in another embodiment, the fixed traces 130 and the stretchable traces 120 are made from the same material, which makes the connection performance between the fixed traces 130 and the stretchable traces 120 better. However, relatively speaking, a total area of the pixel island regions 101 is greater than a total area of the flexible regions 102. If the fixed traces 130 are made from the same material as the stretchable traces 120, this causes an increase in cost. Therefore, the fixed traces 130 disposed on the pixel island regions 101 are made of a metal material or a metal oxide material to transmit signals.

Of course, considering that signal transmission lines in different film layers, such as scanning lines and data lines which have different directions, need to pass through the flexible regions 102 of the display panel 100, it is necessary to provide insulation between the two layers of traces.

FIG. 4 is a top plan schematic diagram of the stretchable traces according to one embodiment of the present disclosure. FIG. 5 is a cross-sectional schematic diagram of the stretchable traces taken along the line B-B shown in FIG. 4. As shown in FIGS. 4-5, in one embodiment, the stretchable traces 120 include first traces 121 and second traces 122. Each of the second traces 122 is disposed on a corresponding one of the first traces 121. The display panel 100 further includes first insulating layers 125. Each of the first traces 121 is insulated from the corresponding one of the second traces 122 through a corresponding one of the first insulating layers 125. In an orthographic projection of the substrate 110, each of the first traces 121 partially overlaps with the corresponding one of the second traces 122.

In the embodiment, an inorganic insulating material and an organic insulating material may be adopted to form the first insulating layers 125. For example, the first insulating layers 125 are made from at least one of silicon oxide materials, silicon nitride materials, and silicon oxynitride materials to achieve an insulating effect. However, since the inorganic insulating material and the organic insulating material have a certain degree of ductility, when the display panel 100 is folded or rolled up, the first insulating layers 125 are folded or rolled accordingly. The stretchable traces 120 are deformed, but a deformation of the first insulating layers 125 made from the inorganic insulating material and the organic insulating material is inconsistent with a deformation of the stretchable traces 120, so the first insulating layers 125 are easy to break, thereby causing the stretchable traces 120 to be compressed and affecting the electrical properties of the stretchable traces 120.

Specifically, the probability of breaking of the conductive hydrogel material at a cross-line position between each of the first traces 121 and the corresponding one of the second traces 122 is much greater than that at other positions of each of the first traces 121 and the corresponding one of the second traces 122 due to multi-layer deformations of the traces. When the first insulating layers 125 are made from the organic insulating material or the inorganic insulating material, multiple deformations thereof may cause at least one of the film layers of the first insulating layers 125 to break, resulting in scratching or compressing the conductive hydrogel material. For this concern, in another embodiment, the first insulating layers 125 in the embodiment are made from an insulating hydrogel material.

In the embodiment, the first traces 121 extend in a first direction X, the second traces 122 extend in a second direction Y, and the first direction X is perpendicular to the second direction Y.

The insulating hydrogel material is prepared by dissolving chitosan (CS) in acrylic acid (AA), and then it is introduced into a hydrophobic association system to synthesize HP (AAm/AA)-CS hydrogel, polymer-doped semi-crystalline polyvinyl alcohol (PVA) hydrogel, and polyacrylic acid (PAAc)/gelatin composite hydrogel. The insulating hydrogel material does not have conductivity. By doping different substances in the hydrogel material, polymer properties thereof are greatly affected. The insulating hydrogel material is made to have a small water absorption and swelling coefficient by doping and has excellent tensile toughness and tensile elasticity.

Relatively speaking, due to multi-layer deformations of the traces, the probability of the conductive hydrogel material at the cross-line positions being broken is much greater than that at other positions. When the insulating hydrogel material is adopted to form the first insulating layers 125, the insulating hydrogel material has an ability to absorb water, and is able to absorb water to promote self-healing when the conductive hydrogel material in a lower layer is broken after multiple deformations, and its own extremely small water absorption and swelling characteristics minimize an impact of the film layers. Moreover, due to the excellent flexibility of the insulating hydrogel material itself, the film layers thereof are basically not broken, and the first traces 121 and the second traces 122 that are insulated by the first insulating layers are effectively protected. Further, when the cross-line positions are deformed, the film layers are subjected to a certain stress. The insulating hydrogel material between the first traces 121 and the second traces 122 disperses the stress and ensures stability of an overall structure. In addition, when the package of the display panel fails, external water vapor may enter the display panel and cause corrosion of the film layers at the cross-line positions. At this time, the insulating hydrogel material further absorbs the water vapor to reduce the impact.

Furthermore, the display panel 100 further includes second insulating layers 126. The second insulating layers 126 are disposed between the first traces 121 and the substrate 110. The second insulating layers 126 are made from at least one of silicon nitride, silicon oxide, and silicon oxynitride. In the embodiment, since there is no need to arrange a wiring layer under the first traces 121, the silicon nitride, the silicon oxide, and the silicon oxynitride are selected as the second insulating layers 126.

In the embodiment, the stretchable traces 120 further include third traces 123, and third traces 123 are disposed above the second traces 122. The display panel 100 further includes third insulating layers 127. Each of the third insulating layers 127 is disposed at an overlapping position of a corresponding one of the second traces 122 and a corresponding one of the third traces 123. Each of the third insulating layers 127 is disposed between the corresponding one of the second traces 122 and the corresponding one of the third traces 123. The third insulating layers 127 are formed of the insulating hydrogel material.

In the embodiment, each of the third insulating layers 127 is only disposed in the overlapping position of the corresponding one of the second traces 122 and the corresponding one of the third traces 123 and does not need to be extended to an entire surface where the third insulating layers are located. After the third traces 123 are manufactured, a planarization layer is formed to planarize the flexible regions 102.

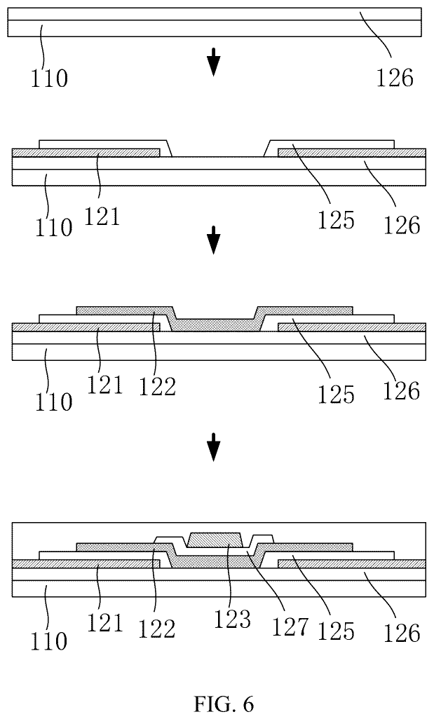

FIG. 6 is a schematic diagram showing a manufacturing process of the stretchable traces according to one embodiment of the present disclosure. As shown in FIG. 6, a manufacturing method of the first traces, the second traces, and the third traces includes depositing the second insulating layer on the substrate, patterning the conductive hydrogel material as a first wiring layer by using technologies such as 3D or 4D printing, soft photoetching, silk-screen printing, direct ink writing, ink-jet printing technology, forming each of the first insulating layers at the connection position of each of the first traces and the corresponding one of the second traces, forming a second wiring layer, forming each of the third insulating layers at the overlapping position of each of the second traces and the corresponding one of the third traces, and finally performing a planarization process after a third wiring layer (where the third traces are located) is formed to complete the manufacturing of the first traces, the second traces, and the third traces.

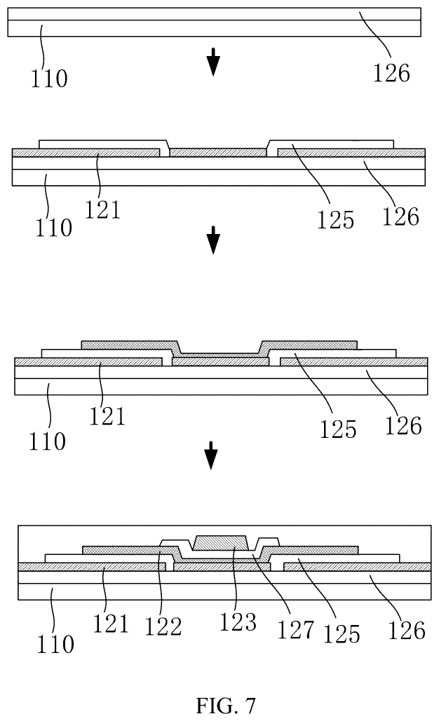

FIG. 7 is another schematic diagram showing the manufacturing process of the stretchable traces according to one embodiment of the present disclosure. As shown in FIG. 7, in another manufacturing method, during the manufacturing process of the first wiring layer, part of the conductive hydrogel material forming the first wiring layer is retained to be connected to the second wiring layer. A retained part of the conductive hydrogel material is not connected to the first wiring layer, and a position where the retained part is located is not the overlapping positions of the first traces and the second traces. Different from FIG. 6, part of the second traces is prepared together with the first layer of the conductive hydrogel material, and the conductive hydrogel material for connecting the second traces is prepared separately at corresponding overlapping positions. Thus, there are two gel layers formed at non-overlapping position to improve the conductivity and stability.

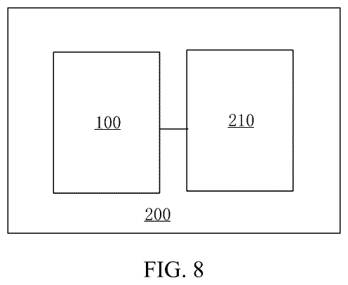

FIG. 8 is a schematic diagram of a display device according to one embodiment of the present disclosure. As shown in FIG. 8, the present disclosure further provides the display device 200. The display device 200 includes a driving circuit 210 and the display panel 100 mentioned above. The driving circuit 210 is configured to drive the display panel 100 to display.

It should be noted that the concept of the present disclosure can form a large number of embodiments, but a length of the document is limited and it is not feasible to list them all individually. Therefore, under the premise of no conflict, the embodiments or technical features described above can be arbitrarily combined to form new embodiments. After the embodiments or technical features are combined, the original technical effects are enhanced.

The above content is a further detailed description of the present disclosure in combination with specific optional implementation methods, and it cannot be determined that the specific implementation of the present disclosure is limited to these descriptions. For those skilled in the art, several simple deductions or substitutions can be made without departing from the concept of the present disclosure, which should be regarded as falling within the protection scope of the present disclosure.

What is claimed is:

1. A display panel, comprising:
a substrate defining pixel island regions disposed in an array and flexible regions;
pixel layers; and
stretchable traces;
wherein each of the flexible regions is defined between corresponding two adjacent pixel island regions, each of the pixel layers is disposed on the substrate and is disposed in a corresponding one of the pixel island regions, and the stretchable traces are disposed on the substrate and are disposed on the flexible regions;
wherein the stretchable traces are made from a conductive hydrogel material; the conductive hydrogel material comprises a hydrogel material and a conductive additive doped in the hydrogel material, and the hydrogel material is a main material of the conductive hydrogel material.

2. The display panel according to claim 1, wherein the hydrogel material comprises a sodium alginate-chitosan quaternary ammonium salt hydrogel material, and the conductive additive comprises at least one of nano-silver particles, copper particles, carbon nanotubes, graphene, and electroactive aniline tetramers.

3. The display panel according to claim 1, wherein the display panel further comprises fixed traces, the fixed traces are disposed on the substrate and are disposed on the pixel island regions, and each of the stretchable traces extends into corresponding two adjacent pixel island regions and is connected to corresponding two of the fixed traces.

4. The display panel according to claim 3, wherein the display panel further comprises conductive connecting portions, and each of the conductive connecting portions wraps a connection joint of a corresponding one of the fixed traces and a corresponding one of the stretchable traces;
wherein the conductive connecting portions are made from a conductive gel material.

5. The display panel according to claim 3, wherein the fixed traces and the stretchable traces are made from the same material.

6. The display panel according to claim 1, wherein the stretchable traces comprise first traces and second traces, each of the second traces is disposed on a corresponding one of the first traces, the display panel further comprises first insulating layers, and each of the first traces is insulated from the corresponding one of the second traces through a corresponding one of the first insulating layers;
wherein each of the first traces partially overlaps with the corresponding one of the second traces in an orthographic projection of the substrate.

7. The display panel according to claim 6, wherein the first traces extend in a first direction, the second traces extend in a second direction, and the first direction is perpendicular to the second direction;
wherein the display panel further comprises a second insulating layer; the second insulating layer is disposed between the first traces and the substrate, the first insulating layers are made from an insulating hydrogel material, and the second insulating layer is made from at least one of silicon nitride, silicon oxide, and silicon oxynitride.

8. The display panel according to claim 6, wherein the stretchable traces further comprise third traces, and the third traces are disposed above the second traces;
wherein the display panel further comprises third insulating layers, each of the third insulating layers is disposed at an overlapping position of a corresponding one of the second traces and a corresponding one of the third traces, each of the third insulating layers is disposed between the corresponding one of the second traces and the corresponding one of the third traces, and the third insulating layers are formed of an insulating hydrogel material.

9. The display panel according to claim 1, wherein the substrate is made from a polymer hydrogel composite material;
wherein metal ions are introduced into the pixel island regions from one side or two sides of the substrate for cross-linking to define the pixel island regions, and regions of the substrate configured as the pixel island regions are rigid.

10. The display panel according to claim 1, wherein the pixel layers comprise light-emitting units, and each of the light-emitting units is disposed on a corresponding one of the pixel island regions;
wherein when the display panel is bent, stretched, rolled up, or folded, each of the light-emitting units disposed on the corresponding one of the pixel island regions is not stretched or bent.

11. A display device, comprising:
a driving circuit; and
a display panel;
wherein the driving circuit is configured to drive the display panel to display;
wherein the display panel comprises a substrate defining pixel island regions disposed in an array, flexible regions, pixel layers, and stretchable traces;
wherein each of the flexible regions is defined between corresponding two adjacent pixel island regions, each of the pixel layers is disposed on the substrate and is disposed in a corresponding one of the pixel island regions, and the stretchable traces are disposed on the substrate and are disposed on the flexible regions;
wherein the stretchable traces are made from a conductive hydrogel material, the conductive hydrogel material comprises a hydrogel material and a conductive additive doped in the hydrogel material, and the hydrogel material is a main material of the conductive hydrogel material.

12. The display device according to claim 11, wherein the hydrogel material comprises a sodium alginate-chitosan quaternary ammonium salt hydrogel material, and the conductive additive comprises at least one of nano-silver particles, copper particles, carbon nanotubes, graphene, and electroactive aniline tetramers.

13. The display device according to claim 11, wherein the display panel further comprises fixed traces, the fixed traces are disposed on the substrate and are disposed on the pixel island regions, and each of the stretchable traces extends into corresponding two adjacent pixel island regions and is connected to corresponding two of the fixed traces.

14. The display device according to claim 13, wherein the display panel further comprises conductive connecting portions, and each of the conductive connecting portions wraps a connection joint of a corresponding one of the fixed traces and a corresponding one of the stretchable traces;
wherein the conductive connecting portions are made from a conductive gel material.

15. The display device according to claim 13, wherein the fixed traces and the stretchable traces are made from the same material.

16. The display device according to claim 11, wherein the stretchable traces comprise first traces and second traces, each of the second traces is disposed on a corresponding one of the first traces, the display panel further comprises first insulating layers; and each of the first traces is insulated from the corresponding one of the second traces through a corresponding one of the first insulating layers;
wherein each of the first traces partially overlaps with the corresponding one of the second traces in an orthographic projection of the substrate.

17. The display device according to claim 16, wherein the first traces extend in a first direction, the second traces extend in a second direction, and the first direction is perpendicular to the second direction;
wherein the display panel further comprises a second insulating layer, the second insulating layer is disposed between the first traces and the substrate, the first insulating layers are made from an insulating hydrogel material, and the second insulating layer is made from at least one of silicon nitride, silicon oxide, and silicon oxynitride.

18. The display device according to claim 16, wherein the stretchable traces further comprise third traces, and the third traces are disposed above the second traces;
wherein the display panel further comprises third insulating layers, each of the third insulating layers is disposed at an overlapping position of a corresponding one of the second traces and a corresponding one of the third traces, each of the third insulating layers is disposed between the corresponding one of the second traces and the corresponding one of the third traces, and the third insulating layers are formed of an insulating hydrogel material.

19. The display device according to claim 11, wherein the substrate is made from a polymer hydrogel composite material;
wherein metal ions are introduced into the pixel island regions from one side or two sides of the substrate for cross-linking to define the pixel island regions, and regions of the substrate configured as the pixel island regions are rigid.
